(19) United States
(12) Patent Application Publication
(10) Pub. No.: US 2026/0215060 A1
(43) Pub. Date: Jul. 23, 2026

(54) DISPLAY PANEL AND DISPLAY DEVICE

(71) Applicant: TIANMA MICROELECTRONICS CO., LTD., Shenzhen City (CN)

(72) Inventors: Qibing WEI, Shenzhen City (CN); Peng ZHANG, Shenzhen City (CN)

(21) Appl. No.: 19/576,840

(22) Filed: Mar. 24, 2026

(30) Foreign Application Priority Data
Nov. 28, 2025 (CN) 202511789730.9

(51) Int. Cl. H10H 29/854; H10H 20/819

(52) U.S. Cl. CPC H10H 29/854; H10H 20/819

(57) ABSTRACT

A display panel includes a substrate, a device layer, and an encapsulation layer. The substrate includes a first edge and a second edge intersecting with each other. An included angle between the first edge and the second edge is a first included angle, and the first included angle is a right angle. The encapsulation layer is located on a side of the device layer away from the substrate, and the encapsulation layer covers the device layer along a direction perpendicular to a plane of the substrate. The encapsulation layer includes a first side structure, a second side structure, and an arc-shaped structure located between the first side structure and the second side structure. The first side structure is adjacent to the first edge, the second side structure is adjacent to the second edge, and an angular bisector of the first included angle passes through the arc-shaped structure.

### CROSS-REFERENCE TO RELATED APPLICATION

The present application claims priority to Chinese Patent Application No. 202511789730.9, filed on Nov. 28, 2025, the content of which is incorporated herein by reference in its entirety.

### TECHNICAL FIELD

The present disclosure relates to the field of display technologies, and in particular, to a display panel and a display device.

### BACKGROUND

In the field of display technologies, an encapsulation layer in a display panel is generally designed to be contracted inward relative to product's outer shape. With the continuous development of display products, a demand for a display panel with a pure square outer shape has appeared in the market. For such a display panel with the pure square outer shape, if the encapsulation layer is still designed to be contracted inward relative to product's outer shape, it is prone to causing the problem of voids or bulging and overflow at the vertex angle of the encapsulation layer, which affects the encapsulation reliability. Therefore, there is an urgent need for a new solution.

### SUMMARY

A first aspect of the present disclosure provides a display panel. The display panel includes a substrate, a device layer, and an encapsulation layer. The substrate includes a first edge and a second edge intersecting with each other, the first edge extends along a first direction, the second edge extends along a second direction, the first direction intersects with the second direction, an included angle between the first edge and the second edge is a first included angle, and the first included angle is a right angle. The device layer is located on one side of the substrate. The encapsulation layer is located on a side of the device layer away from the substrate, and the encapsulation layer covers the device layer along a direction perpendicular to a plane of the substrate. The encapsulation layer includes a first side structure, a second side structure, and an arc-shaped structure located between the first side structure and the second side structure. The first side structure is adjacent to the first edge, the second side structure is adjacent to the second edge, and an angular bisector of the first included angle passes through the arc-shaped structure.

Another aspect of the present disclosure provides a display device. The display device includes a display panel. The display panel includes a substrate, a device layer, and an encapsulation layer. The substrate includes a first edge and a second edge intersecting with each other, the first edge extends along a first direction, the second edge extends along a second direction, the first direction intersects with the second direction, an included angle between the first edge and the second edge is a first included angle, and the first included angle is a right angle. The device layer is located on one side of the substrate. The encapsulation layer is located on a side of the device layer away from the substrate, and the encapsulation layer covers the device layer along a direction perpendicular to a plane of the substrate. The encapsulation layer includes a first side structure, a second side structure, and an arc-shaped structure located between the first side structure and the second side structure. The first side structure is adjacent to the first edge, the second side structure is adjacent to the second edge, and an angular bisector of the first included angle passes through the arc-shaped structure.

### BRIEF DESCRIPTION OF DRAWINGS

In order to better illustrate the technical solutions in embodiments of the present disclosure, the drawings used in the description of embodiments are briefly described as below. It should be noted that the drawings described below are merely some embodiments of the present disclosure, and other drawings may be obtained by those skilled in the art according to these drawings.

FIG. 1 is a planar schematic diagram of a display panel according to some embodiments of the present disclosure;

FIG. 2 is a schematic structural diagram of a display panel according to some embodiments of the present disclosure;

FIG. 3 is a partially enlarged schematic diagram of a display panel according to some embodiments of the present disclosure;

FIG. 4 is a partially enlarged schematic diagram of a display panel according to some embodiments of the present disclosure;

FIG. 5 is a partially enlarged schematic diagram of a display panel according to some embodiments of the present disclosure;

FIG. 6 is a partially enlarged schematic diagram of a display panel according to some embodiments of the present disclosure;

FIG. 7 is a partially enlarged schematic diagram of a display panel according to some embodiments of the present disclosure;

FIG. 8A is a partially enlarged schematic diagram of a display panel according to some embodiments of the present disclosure;

FIG. 8B is a cross-sectional schematic diagram along line AA′ in FIG. 8A according to some embodiments of the present disclosure;

FIG. 9 is a partially enlarged schematic diagram of a display panel according to some embodiments of the present disclosure;

FIG. 10 is a partially enlarged schematic diagram of a display panel according to some embodiments of the present disclosure;

FIG. 11 is a comparative cross-sectional schematic diagram of a first gap retaining wall and a first side retaining wall according to some embodiments of the present disclosure;

FIG. 12 is a partially enlarged schematic diagram of a display panel according to some embodiments of the present disclosure;

FIG. 13 is a partially enlarged schematic diagram of a display panel according to some embodiments of the present disclosure;

FIG. 14 is a partially enlarged schematic diagram of a display panel according to some embodiments of the present disclosure;

FIG. 15 is a comparative cross-sectional schematic diagram of a second gap retaining wall and a second side retaining wall according to some embodiments of the present disclosure;

FIG. 16A is a partially enlarged schematic diagram of a display panel according to some embodiments of the present disclosure;

FIG. 16B is a partially enlarged schematic diagram of a display panel according to some embodiments of the present disclosure;

FIG. 16C is a partially enlarged schematic diagram of a display panel according to some embodiments of the present disclosure;

FIG. 16D is a partially enlarged schematic diagram of a display panel according to some embodiments of the present disclosure; and

FIG. 17 is a schematic diagram of a display device according to some embodiments of the present disclosure.

### DESCRIPTION OF EMBODIMENTS

In order to better understand technical solutions of the present disclosure, the embodiments of the present disclosure are described in details with reference to the drawings.

It should be clear that the described embodiments are merely part of the embodiments of the present disclosure rather than all of the embodiments. All other embodiments obtained by those skilled in the art shall fall into the protection scope of the present disclosure.

The terms used in the embodiments of the present disclosure are merely for the purpose of describing specific embodiment, rather than limiting the present disclosure. The terms “a”, “an”, “the” and “said” in a singular form in the embodiment of the present disclosure and the attached claims are also intended to include plural forms thereof, unless noted otherwise.

It should be understood that the term “and/or” used in the context of the present disclosure is to describe a correlation relation of related objects, indicating that there may be three relations, e.g., A and/or B may indicate only A, both A and B, and only B. In addition, the symbol “/” in the context generally indicates that the relation between the objects in front and at the back of “/” is an “or” relationship.

Various modifications and variations may be made in the present disclosure without departing from the spirit or scope of the present disclosure, which will be apparent to those skilled in the art. Accordingly, the present disclosure is intended to cover the modifications and variations of the present disclosure that fall within the scope of corresponding claims (the claimed technical solutions) and their equivalents. It should be noted that, the implementations provided in the embodiments of the present disclosure can be combined with each other if no conflict occurs.

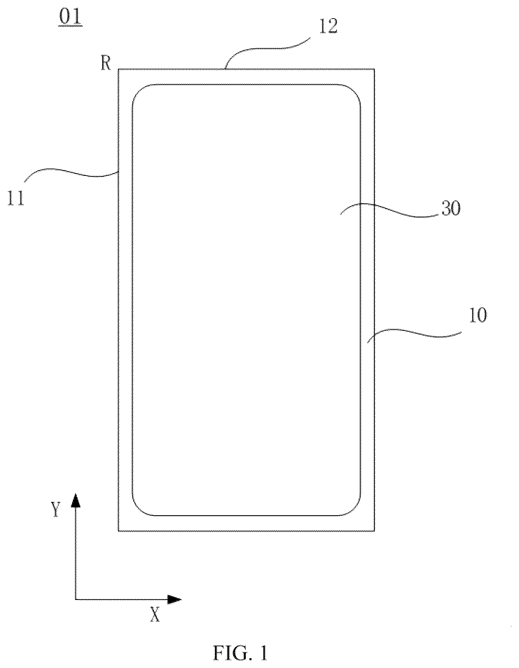

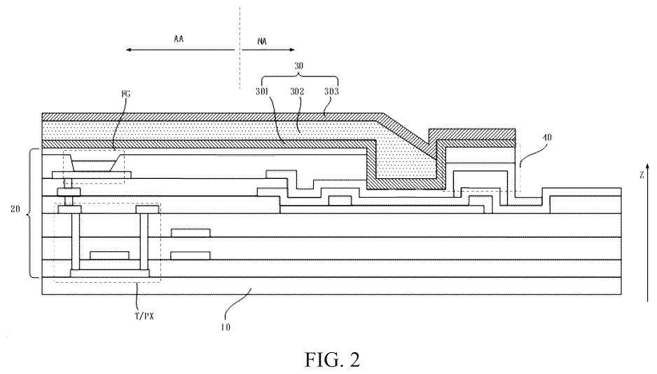

FIG. 1 is a planar schematic diagram of a display panel according to some embodiments of the present disclosure, and FIG. 2 is a schematic structural diagram of a display panel according to some embodiments of the present disclosure.

Some embodiments of the present disclosure provide a display panel 01. As shown in FIG. 1 and FIG. 2, the display panel 01 includes a substrate 10, a device layer 20, and an encapsulation layer 30. The substrate 10 includes a first edge 11 and a second edge 12 intersecting with each other. The first edge 11 extends along a first direction Y, and the second edge 12 extends along a second direction X. The first direction Y intersects with the second direction X.

For example, the first direction Y is one of a column direction and a row direction of the display panel 01, and the second direction X is the other one of the column direction and the row direction of the display panel 01.

An included angle between the first edge 11 and the second edge 12 is a first included angle R, and the first included angle R is a right angle. That is, at least one vertex angle of the substrate 10 is a right angle.

For example, as shown in FIG. 1, four vertex angles of the substrate 10 may all be right angles, and the substrate 10 is square in outer shape.

As shown in FIG. 2, the device layer 20 is located on one side of the substrate 10 and includes a plurality of transistors T and a light-emitting device FG. The plurality of transistors T may form a pixel circuit PX, and the pixel circuit PX is electrically connected to the light-emitting device FG for driving the light-emitting device FG to emit light.

The encapsulation layer 30 is located on a side of the device layer 20 away from the substrate 10. The encapsulation layer 30 covers the device layer 20 along a direction Z perpendicular to a plane of the substrate 10. The encapsulation layer 30 may be configured to protect a device in the device layer 20 to prevent external moisture and oxygen from eroding the device in the display panel 01. It is understandable that, the encapsulation layer 30 may cover a display region AA of the display panel 01 and be cut off in a frame region NA.

For example, as shown in FIG. 2, the encapsulation layer 30 includes a first inorganic layer 301, a first organic layer 302 and a second inorganic layer 303, and the first organic layer 302 is located between the first inorganic layer 301 and the second inorganic layer 302. The first inorganic layer 301 and the second inorganic layer 303 mainly function to isolate moisture and oxygen, and the first organic layer 302 mainly serves to planarize an interface and buffer stress. A retaining wall structure is generally provided in the edge region of the encapsulation layer 30, and the first inorganic layer 301 and the second inorganic layer 303 are connected to each other on the retaining wall structure, so as to prevent the first organic layer 302 from overflowing, thereby ensuring the encapsulation reliability.

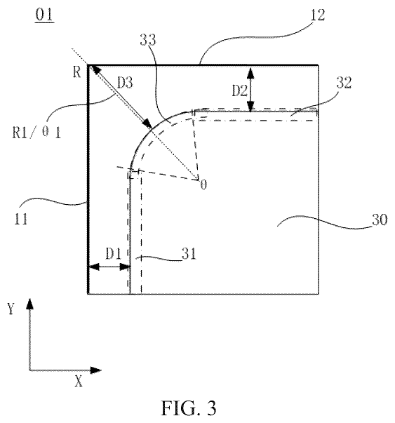

FIG. 3 is a partially enlarged schematic diagram of a display panel according to some embodiments of the present disclosure. Referring to FIG. 3, the encapsulation layer 30 includes a first side structure 31, a second side structure 32, and an arc-shaped structure 33 located between the first side structure 31 and the second side structure 32. The arc-shaped structure 33 may protrude toward the first included angle R.

The first side structure 31 is adjacent to the first edge 11, and the second side structure 32 is adjacent to the second edge 12. An angular bisector R1 of the first included angle R passes through the arc-shaped structure 33. The first side structure 31 may refer to a portion of the encapsulation layer 30 adjacent to the first edge 11. The second side structure 32 may refer to a portion of the encapsulation layer 30 adjacent to the second edge 12. The arc-shaped structure 33 may refer to a portion between the first side structure 31 and the second side structure 32 facing the vertex of the first included angle R. The first organic layer 302 may be cut off at the inner wall of the first side structure 31, the second side structure 32, and the arc-shaped structure 33 away from the edge of the display panel 01.

That is, in the edge portion of the encapsulation layer 30 facing the first included angle R, the inner wall of the encapsulation layer 30 away from the edge of the display panel 01 may be configured to be relatively smooth.

It has found through research that, in the related art, when the included angle between the first edge and the second edge connected to each other in the substrate is a right angle, if the portion of the encapsulation layer adjacent to the right angle is also configured to be a pure right-angle structure, under the current display panel preparation technology, since the corner of the right-angle structure is relatively steep, the first organic layer in the encapsulation layer is not prone to smoothly overflow to the vertex of the right-angle structure, which easily causes voids or bulging and overflow at the vertex of the right-angle structure of the encapsulation layer, thereby affecting the encapsulation reliability.

In view of this, in some embodiments of the present disclosure, the arc-shaped structure 33 is arranged between the first side structure 31 and the second side structure 32, and the angle bisector R1 of the first included angle R passes through the arc-shaped structure 33, so that a portion of the encapsulation layer 30 adjacent to the vertex of the first included angle R includes the arc-shaped structure 33, which is beneficial to avoid a relatively steep corner when the first side structure 31 of the encapsulation layer 30 transitions to the second side structure 32 through the arc-shaped structure 33, thereby solving the problem of voids or bulging and overflow in the region of the encapsulation layer 30 adjacent to the first included angle R, and further improving the encapsulation reliability of the encapsulation layer 30.

As shown in FIG. 3, in some embodiments of the present disclosure, the minimum distance between the first side structure 31 and the first edge 11 is D1, the minimum distance between the second side structure 32 and the second edge 12 is D2, and the minimum distance between the vertex of the first included angle R and the arc-shaped structure 33 is D3.

D3 is greater than a lesser one of D1 and D2. That is, if D1<D2, then D3>D1; if D1>D2, then D3>D2; if D1=D2, then D3>D1=D2.

In some embodiments of the present disclosure, D3 is greater than a lesser one of D1 and D2, so that when the arc-shaped structure 33 protrudes toward the first included angle R, it is beneficial to avoid that the arc-shaped structure 33 is too close to the vertex of the first included angle R, reducing the probability that the arc-shaped structure 33 is damaged when the first included angle R is collided, that is, reducing the probability that the encapsulation layer 30 is damaged, thereby improving the service life of the display panel 01.

In some embodiments of the present disclosure, continuing to refer to FIG. 3, D3 is not greater than three times of a greater one of D1 and D2. That is, if D1>D2, then D3≤3* D1; if D1<D2, then D3≤3*D2; and if D1=D2, then D3≤3*D1=3*D2.

Based on such an arrangement manner, the arc-shaped structure 33 may not be too far away from the vertex of the first included angle R, which is beneficial to avoiding the problem that the area of the display region AA in the display panel 01 is excessively compressed due to the reduction of the area of the encapsulation layer 30, thereby ensuring that the display panel 01 has a relatively large screen-to-body ratio and improving the user experience.

In some embodiments of the present disclosure, the central angle corresponding to the arc-shaped structure 33 is not greater than 180°. In this way, the arc length of the arc-shaped structure 33 will not be too large, which is beneficial to avoiding that the overall outer shape of the encapsulation layer 30 differs too much from the outer shape of the substrate 10. As a result, the encapsulation layer 30 can occupy a relatively large area and cover a larger display area, thereby ensuring that the display panel 01 has a relatively large screen-to-body ratio and improving the user experience.

In some embodiments of the present disclosure, continuing to refer to FIG. 3, one end of the arc-shaped structure 33 is connected to the first side structure 31, and another end of the arc-shaped structure 33 is connected to the second side structure 32. That is, the arc-shaped structure 33 may be directly connected to the first side structure 31 and the second side structure 32.

In some embodiments of the present disclosure, the arc-shaped structure 33 is configured to be directly connected to the first side structure 31 and the second side structure 32, so that the corner between the arc-shaped structure 33 and the first side structure 31 is greater than 90°, and the corner between the arc-shaped structure 33 and the second side structure 32 is greater than 90°, which is beneficial to improving the smoothness of the transition from the first side structure 31 to the second side structure 32 through the arc-shaped structure 33, thereby helping to ensure the encapsulation reliability.

In some embodiments of the present disclosure, as shown in FIG. 3, the central angle corresponding to the arc-shaped structure 33 is a second included angle θ, and the angular bisector of the second included angle θ coincides with the angular bisector of the first included angle R. That is, the circle center corresponding to the arc-shaped structure 33, the arc top of the arc-shaped structure 33, and the vertex of the first included angle R may be located on the same straight line.

Based on such an arrangement manner, the arc-shaped structure 33 may be symmetrical along the angular bisector of the first included angle R, improving the smoothness between the arc-shaped structure 33, and the first side structure 31 and the second side structure 32, and enabling the degree of the corner between the arc-shaped structure 33 and the first side structure 31 to approach the degree of the corner between the arc-shaped structure 33 and the second side structure 32, which is beneficial to reducing the complexity of the encapsulation layer 30 and saving the process preparation cost.

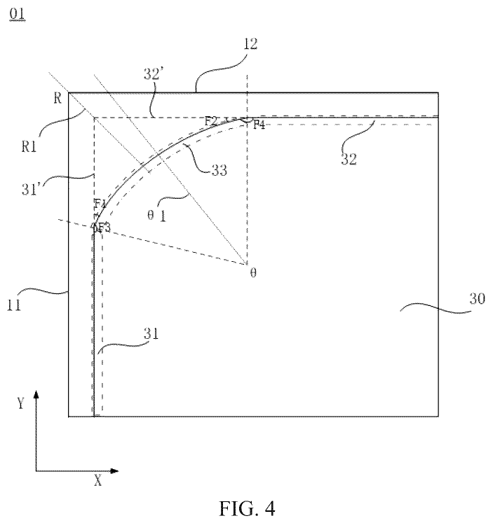

FIG. 4 is a partial enlarged schematic diagram of a display panel according to some embodiments of the present disclosure. In some embodiments of the present disclosure, as shown in FIG. 4, the central angle corresponding to the arc-shaped structure 33 is a second included angle θ, and the angle bisector θ1 of the second included angle θ does not coincide with the angle bisector R1 of the first included angle R. That is, the angle bisector θ1 of the second included angle θ may not pass through the vertex of the first included angle R.

Based on such an arrangement manner, the degree of the corner between the arc-shaped structure 33 and the first side structure 31 may be different from the degree of the corner between the arc-shaped structure 33 and the second side structure 32, which is beneficial to enabling the space at the position with a relatively large corner degree to be relatively large, thereby generating an avoidance space at the position with the relatively large corner degree, facilitating the arrangement of devices at the position with the relatively large corner degree, and improving the space utilization rate of the display panel 01.

In addition, when preparing the first organic layer 302, the first organic layer 302 may be leveled at the position with the relatively large corner degree, which is beneficial to reducing the risk of overflow of the first organic layer 302.

For example, as shown in FIG. 4, the extension line 31′ of the first side structure 31 intersects with the extension line 32′ of the second side structure 32. The included angle between the arc-shaped structure 33 and the extension line 31′ of the first side structure 31 is a third included angle F1, and the included angle between the arc-shaped structure 33 and the extension line 32′ of the second side structure 32 is a fourth included angle F2. The angle degree of the third included angle F1 is different from the angle degree of the fourth included angle F2.

Further, the corner between the arc-shaped structure 33 and the first side structure 31 is a fifth included angle F3, and the corner between the arc-shaped structure 33 and the second side structure 32 is a sixth included angle F4.

Since the sum of the fifth included angle F3 and the third included angle F1 is 180°, and the sum of the sixth included angle F4 and the fourth included angle F2 is 180°, the angle degree of the third included angle F1 is configured to be different from the angle degree of the fourth included angle F2, so that the degree of the fifth included angle F3 is different from the degree of the sixth included angle F4. That is, the degree of the corner between the arc-shaped structure 33 and the first side structure 31 is different from the degree of the corner between the arc-shaped structure 33 and the second side structure 32.

During preparing the first organic layer 302 in the encapsulation layer 30, as shown in FIG. 4, if the degree of the corner between the arc-shaped structure 33 and the second side structure 32 is relatively large, that is, the degree of the sixth included angle F4 is relatively large, the leveling of the first organic layer 302 may be performed along the second direction X, so that when the first organic layer 302 overflows to the sixth included angle F4, the sixth included angle F4 has sufficient space to accommodate the first organic layer 302, thereby reducing the risk of overflow of the first organic layer 302.

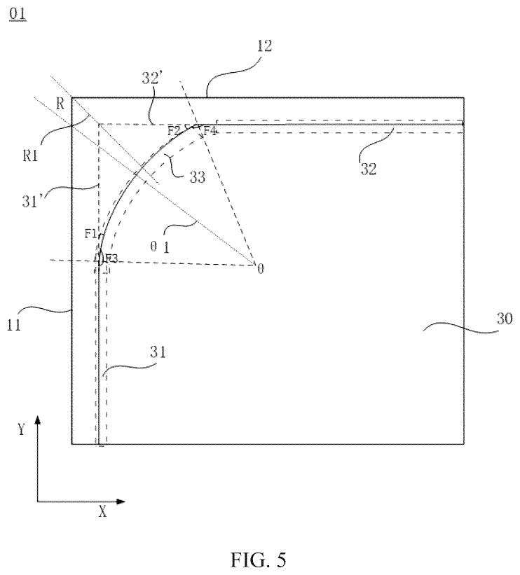

FIG. 5 is a partial enlarged schematic diagram of a display panel according to some embodiments of the present disclosure. As shown in FIG. 5, if the degree of the corner between the arc-shaped structure 33 and the first side structure 31 is relatively large, that is, the degree of the fifth included angle F3 is relatively large, the leveling of the first organic layer 302 may be performed along the first direction Y, so that when the first organic layer 302 overflows to the fifth included angle F3, the fifth included angle F3 has sufficient space to accommodate the first organic layer 302, thereby reducing the risk of overflow of the first organic layer 302.

In some embodiments of the present disclosure, the first organic layer 302 is prepared by means of inkjet printing (IJP).

In some embodiments of the present disclosure, continuing to refer to FIG. 3, one end of the arc-shaped structure 33 is connected to the end of the first side structure 31 facing the second edge 12, and another end of the arc-shaped structure 33 is connected to the end of the second side structure 32 facing the first edge 11. That is, the arc-shaped structure 33 is respectively connected to the end of the first side structure 31 and the end of the second side structure 32, and the arc-shaped structure 33 may be arranged adjacent to the vertex of the first included angle R.

In some embodiments of the present disclosure, the arc-shaped structure 33 is directly connected to the end of the first side structure 31 and the end of the second side structure 32, realizing the smooth transition from the first side structure 31 to the second side structure 32 through the arc-shaped structure 33, reducing the structural complexity of the encapsulation layer 30 and reducing the preparation difficulty of the encapsulation layer 30.

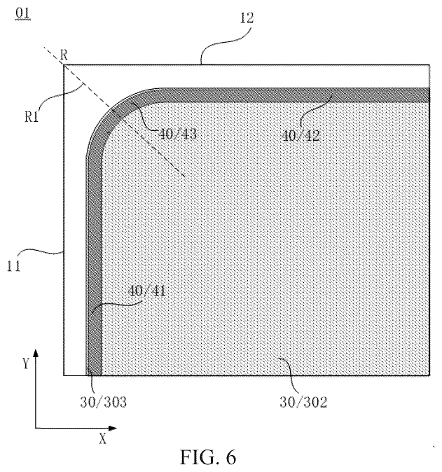

FIG. 6 is a partially enlarged schematic diagram of a display panel according to some embodiments of the present disclosure.

As shown in FIG. 2 and FIG. 6, in some embodiments of the present disclosure, the display panel 01 includes a first retaining wall structure 40. The encapsulation layer 30 includes a first inorganic layer 301, a first organic layer 302, and a second inorganic layer 303, and the first organic layer 302 is located between the first inorganic layer 301 and the second inorganic layer 303. The first inorganic layer 301 and the second inorganic layer 303 are connected to each other at the first retaining wall structure 40, and the first retaining wall structure 40 is configured to block the first organic layer 302 from overflowing.

For example, the first organic layer 302 is prepared by means of inkjet printing (IJP).

The first retaining wall structure 40 includes a first side retaining wall 41, a second side retaining wall 42 and an arc-shaped retaining wall 43. The first side retaining wall extends along the first direction Y, and the second side retaining wall 42 extends along the second direction X. The first side structure 31 of the encapsulation layer 30 is arranged on the first side retaining wall 41, the second side structure 32 of the encapsulation layer 30 is arranged on the second side retaining wall 42, and the arc-shaped structure 33 of the encapsulation layer 30 is arranged on the arc-shaped retaining wall 43.

That is, in the encapsulation layer 30, the first side structure 31 may refer to a portion where the first inorganic layer 301 and the second inorganic layer 303 are connected to each other on the first side retaining wall 41. The second side structure 32 may refer to a portion where the first inorganic layer 301 and the second inorganic layer 303 are connected to each other on the second side retaining wall 42. The arc-shaped structure 33 may refer to a portion where the first inorganic layer 301 and the second inorganic layer 303 are connected to each other on the arc-shaped retaining wall 43. The first organic layer 302 is cut off at the inner wall of the first side retaining wall 41, the second side retaining wall 42 and the arc-shaped retaining wall 43 away from the edge of the display panel 01.

In some embodiments of the present disclosure, the first retaining wall structure 40 may be configured to block the overflow of the first organic layer 302 in the encapsulation layer 30, so as to determine the edge portion of the encapsulation layer 30.

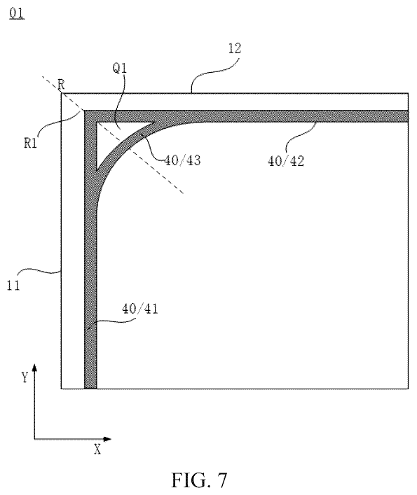

FIG. 7 is a partially enlarged schematic diagram of a display panel according to an embodiment of the present disclosure.

In some embodiments of the present disclosure, as shown in FIG. 7, one end of the arc-shaped retaining wall 43 is connected to the first side retaining wall 41, and another end of the arc-shaped retaining wall 43 is connected to the second side retaining wall 42. The first side retaining wall 41 intersects with the second side retaining wall 42. The vertex where the first side retaining wall 41 intersects with the second side retaining wall 42 is located between the vertex of the first included angle R and the arc-shaped retaining wall 43.

That is, on the side of the arc-shaped retaining wall 43 facing the first included angle R, there further exists a first region Q1 enclosed by the first side retaining wall 41, the arc-shaped retaining wall 43, and the second side retaining wall 42.

In some embodiments of the present disclosure, a first region Q1 is further provided on the side of the arc-shaped retaining wall 43 facing the first included angle R, so that during preparing the encapsulation layer 30, the first inorganic layer 301 and the second inorganic layer 303 in the encapsulation layer 30 may extend from the arc-shaped retaining wall 43 to the first region Q1 and the first side retaining wall 41 and the second side retaining wall 42 that enclose the first region Q1. When using the arc-shaped retaining wall 43 to block the overflow of the first organic layer 302, even if the first organic layer 302 overflows out from the arc-shaped retaining wall 43 and enters the first region Q1, the arc-shaped retaining wall 43 may be blocked by the first side retaining wall 41 and the second side retaining wall 42 that enclose the first region Q1, which is beneficial to further improving the encapsulation reliability of the encapsulation layer 30.

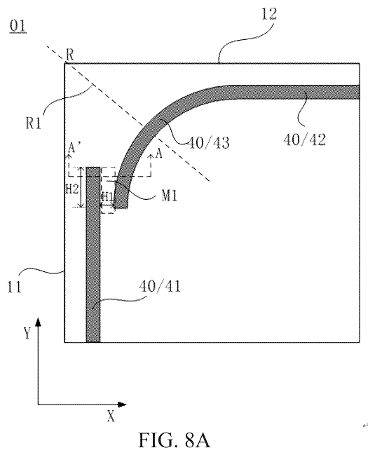

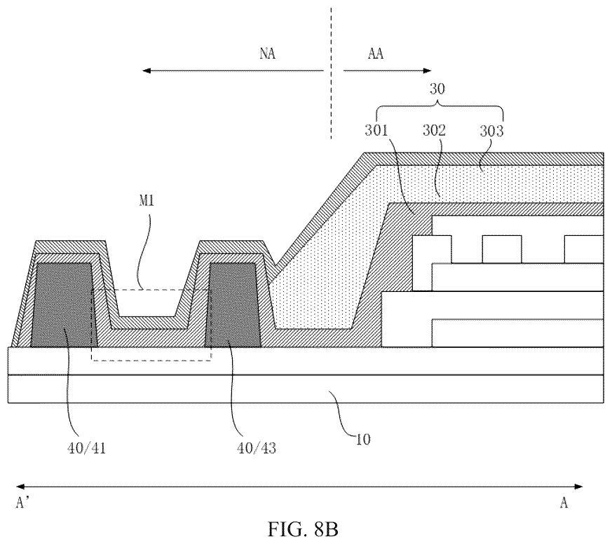

FIG. 8A is a partially enlarged schematic diagram of a display panel according to some embodiments of the present disclosure, and FIG. 8B is a cross-sectional schematic diagram taken along line AA′ in FIG. 8A.

As shown in FIG. 8A, in some embodiments of the present disclosure, the first side retaining wall 41 is separated from the arc-shaped retaining wall 43. Along the second direction X, the first side retaining wall 41 overlaps with the arc-shaped retaining wall 43.

As shown in FIG. 8B, a first gap M1 between the first side retaining wall 41 and the arc-shaped retaining wall 43, and the first inorganic layer 301 is connected to the second inorganic layer 302 in the first gap M1. It is understandable that, the first inorganic layer 301 and the second inorganic layer 302 are also connected to each other on first retaining wall structures on two sides of the first gap M1.

In some embodiments of the present disclosure, the first side retaining wall 41 is arranged to be separated from the arc-shaped retaining wall 43, and the first gap M1 exists between the first side retaining wall 41 and the arc-shaped retaining wall 43, so that during preparing the first organic layer 302 in the encapsulation layer 30, the existence of the first gap M1 facilitates the overflow of the first organic layer 302, thereby facilitating enabling the overflow of the first organic layer 302 in the display panel 01 to be relatively flat, and reducing the risk of voids or bulging occurs in the region of the encapsulation layer 30 adjacent to the first included angle R.

In addition, the first inorganic layer 301 is connected the second inorganic layer 303 in the first gap M1, so as to increase the connecting area of the first inorganic layer 301 and the second inorganic layer 303, to prevent the first organic layer 302 from overflowing out from the first gap M1, and to ensure the encapsulation reliability.

In some embodiments of the present disclosure, as shown in FIG. 8A, the minimum distance between the first side retaining wall 41 and the arc-shaped retaining wall 43 is H1, and the overlapping length of the first side retaining wall 41 and the arc-shaped retaining wall 43 along the second direction X is H2. That is, the distance that the first gap M1 extends along the first direction Y may be H2, where H2>H1.

That is, the distance that the first gap M1 extends along the first direction Y is greater than the width of the first gap M1 along the second direction X.

Based on such an arrangement manner, the first gap M1 between the first side retaining wall 41 and the arc-shaped retaining wall 43 may extend a relatively large distance along the first direction Y, thereby further avoiding the possibility that the first organic layer 302 overflows from the first gap M1 during preparing the first organic layer 302, and further improving the encapsulation reliability.

In some embodiments of the present disclosure, continuing to refer to FIG. 8A, the arc-shaped retaining wall 43 is located on a side of the first side retaining wall 41 away from the first edge 11.

In some embodiments of the present disclosure, the arc-shaped retaining wall 43 is arranged on the side of the first side retaining wall 41 away from the first edge 11, which is beneficial to avoiding that the arc-shaped retaining wall 43 is too close to the vertex of the first included angle R, thereby avoiding that the arc-shaped structure 33 on the arc-shaped retaining wall 43 is too close to the first included angle R, reducing the probability that the arc-shaped structure 33 is damaged when the first included angle R is collided, that is, reducing the probability that the encapsulation layer 30 is damaged, and improving the service life of the display panel 01.

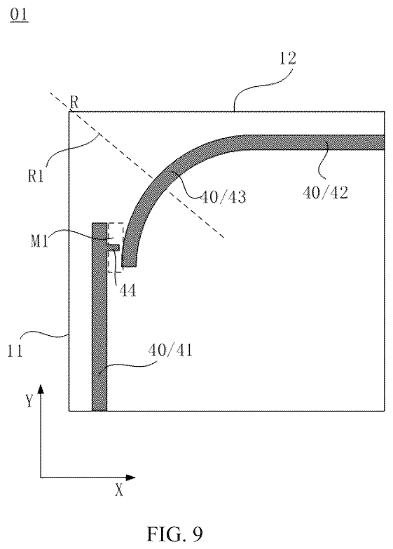

FIG. 9 is a partially enlarged schematic diagram of a display panel according to some embodiments of the present disclosure.

As shown in FIG. 9, in some embodiments of the present disclosure, the first retaining wall structure 40 further includes a first gap retaining wall 44 located between the first side retaining wall 41 and the arc-shaped retaining wall 43. That is, the first gap retaining wall 44 may be arranged in the first gap M1.

The first gap retaining wall 44 extends along the second direction X, and one of the first side retaining wall 41 and the arc-shaped retaining wall 43 is connected to the first gap retaining wall 44.

In some embodiments of the present disclosure, the first gap retaining wall 44 is arranged between the arc-shaped retaining wall 43 and the first side retaining wall 41, so that the first gap retaining wall 44 can be used to block the first organic layer 302 that overflows to the first gap M1, which is beneficial to further preventing the first organic layer 302 from overflowing out from the first gap M1, thereby further improving the encapsulation reliability.

As an example, as shown in FIG. 9, the first gap retaining wall 44 is closer to the second edge 12 than the end of the arc-shaped retaining wall 43 adjacent to the first side retaining wall 41. In this way, on the one hand, it is beneficial to avoiding that the first gap retaining wall 44 completely blocks the first gap M1, thereby affecting the requirement for the first organic layer 302 to overflow to the first gap M1 during leveling, and on the other hand, it is beneficial to avoiding a steep corner when the first organic layer 302 transitions from the first side retaining wall 41 to the arc-shaped retaining wall 43.

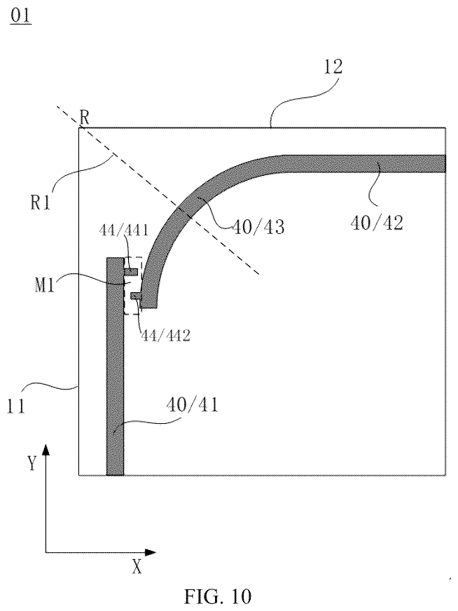

FIG. 10 is a partially enlarged schematic diagram of a display panel according to some embodiments of the present disclosure.

In some embodiments of the present disclosure, as shown in FIG. 10, a plurality of first gap retaining walls 44 are formed between the first side retaining wall 41 and the arc-shaped retaining wall 43, and the plurality of first gap retaining walls 44 are arranged along the first direction Y. Along the first direction Y, at least some of the first gap retaining walls 44 overlap.

For example, as shown in FIG. 10, the first gap retaining walls 44 include a first sub-gap retaining wall 441 and a second sub-gap retaining wall 442. The first sub-gap retaining wall 441 is located on a side of the second sub-gap retaining wall 442 adjacent to the second edge 12. The first sub-gap retaining wall 441 is connected to the first side retaining wall 41 and is separated from the arc-shaped retaining wall 43. The second sub-gap retaining wall 442 is connected to the arc-shaped retaining wall 43 and is separated from the first side retaining wall 41.

Along the first direction Y, the first sub-gap retaining wall 441 overlaps with the second sub-gap retaining wall 442.

In some embodiments of the present disclosure, a plurality of first gap retaining walls 44 are formed between the first side retaining wall 41 and the arc-shaped retaining wall 43, and the plurality of first gap retaining walls 44 are arranged along the first direction Y, which is beneficial to sequentially blocking the first organic layer 302 using the first gap retaining walls 44, thereby further improving the possibility of preventing the first organic layer 302 from overflowing out from the first gap M1, and improving the encapsulation reliability.

In addition, at least some of the first gap retaining walls 44 overlap along the first direction Y, which is beneficial to enabling the first gap retaining walls 44 to comprehensively block the first organic layer 302 flowing into the first gap M1 along the second direction X, thereby improving the possibility of preventing the first organic layer 302 from overflowing out from the first gap M1.

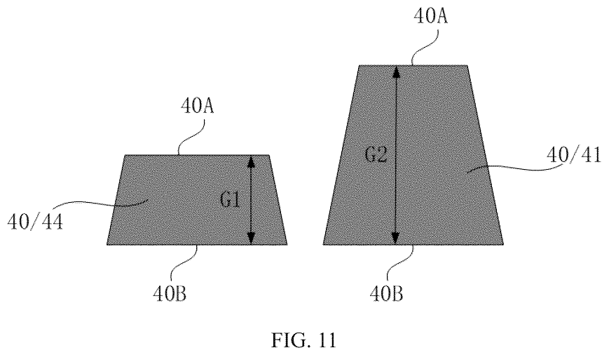

FIG. 11 is a comparative cross-sectional schematic diagram of a first gap retaining wall and a first side retaining wall according to some embodiments of the present disclosure.

In some embodiments of the present disclosure, as shown in FIG. 8A and FIG. 10, the height G1 of the first gap retaining wall 44 is less than the height G2 of the first side retaining wall 41. That is, G1<G2.

As shown in FIG. 10, in the display panel 01, the cross-section of the first retaining wall structure 40 along the thickness direction is generally an isosceles trapezoid. The first retaining wall structure 40 includes an “upper” surface 40A and a “lower” surface 40B, and the “upper” surface 40A is located on a side of the “lower” surface 40B away from the substrate 10.

It has found through research that the first retaining wall structure 40 is generally composed of a plurality of film layers. The higher the first retaining wall structure 40 is, the smaller the area of the “upper” surface of the first retaining wall structure 40 is generally. Therefore, in some embodiments of the present disclosure, the height G1 of the first gap retaining wall 44 is less than the height G2 of the first side retaining wall 41, which can enable the area of the “upper” surface 40A in the first gap retaining wall 44 to be relatively large, thereby helping to increase the connection area between the first inorganic layer 301 and the second inorganic layer 303 on the “upper” surface 40A of the first gap retaining wall 44, improving the blocking capability of the first organic layer 302, and further improving the possibility of preventing the first organic layer 302 from overflowing out from the first gap M1.

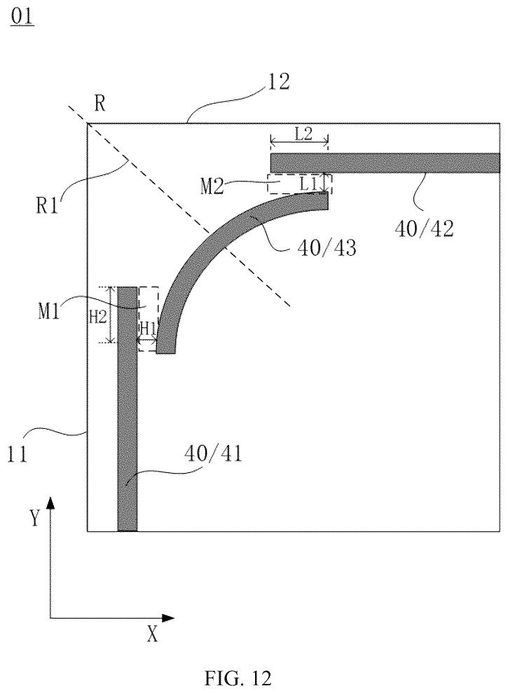

FIG. 12 is a partially enlarged schematic diagram of a display panel according to some embodiments of the present disclosure.

In some embodiments of the present disclosure, as shown in FIG. 12, the second side retaining wall 42 is separated from the arc-shaped retaining wall 43, and the second side retaining wall 42 overlaps with the arc-shaped retaining wall 43 along the first direction Y.

A second gap M2 exists between the second side retaining wall 42 and the arc-shaped retaining wall 43, and the first inorganic layer 301 is connected to the second inorganic layer 302 in the second gap M2. It is understandable that, the first inorganic layer 301 and the second inorganic layer 302 are also connected to each other on first retaining wall structures on two sides of the second gap M2.

In some embodiments of the present disclosure, the second side retaining wall 42 is arranged to be separated from the arc-shaped retaining wall 43, and the second gap M2 exists between the second side retaining wall 42 and the arc-shaped retaining wall 43, so that during preparing the first organic layer 302 in the encapsulation layer 30, the existence of the second gap M2 facilitates the overflow of the first organic layer 302, thereby facilitating enabling the overflow of the first organic layer 302 in the display panel 01 to be relatively flat, and reducing the risk of voids or bulging occurs in the region of the encapsulation layer 30 adjacent to the first included angle R.

In addition, the first inorganic layer 301 is connected the second inorganic layer 303 in the second gap M2, so as to increase the connecting area of the first inorganic layer 301 and the second inorganic layer 303, to prevent the first organic layer 302 from overflowing out from the second gap M2, and to ensure the encapsulation reliability.

In some embodiments of the present disclosure, as shown in FIG. 12, the minimum distance between the second side retaining wall 42 and the arc-shaped retaining wall 43 is L1, and the overlapping length of the second side retaining wall 42 and the arc-shaped retaining wall 43 along the first direction Y is L2. That is, the distance that the second gap M2 extends along the second direction X may be L2, where L2>L1.

That is, the distance that the second gap M2 extends along the second direction X is greater than the width of the second gap M2 along the first direction Y.

Based on such an arrangement, the second gap M2 between the second side retaining wall 42 and the arc-shaped retaining wall 43 may extend a relatively large distance along the second direction X, thereby further avoiding the possibility that the first organic layer 302 overflows from the first gap M1 during preparing the first organic layer 302, and further improving the encapsulation reliability.

In some embodiments of the present disclosure, continuing to refer to FIG. 12, the arc-shaped retaining wall 43 is located on a side of the second side retaining wall 42 away from the second edge 12.

In some embodiments of the present disclosure, the arc-shaped retaining wall 43 is arranged on the side of the second side retaining wall 42 away from the second edge 12, which is beneficial to avoiding that the arc-shaped retaining wall 43 is too close to the vertex of the first included angle R, thereby avoiding that the arc-shaped structure 33 on the arc-shaped retaining wall 43 is too close to the first included angle R, reducing the probability that the arc-shaped structure 33 is damaged when the first included angle R is collided, that is, reducing the probability that the encapsulation layer 30 is damaged, and improving the service life of the display panel 01.

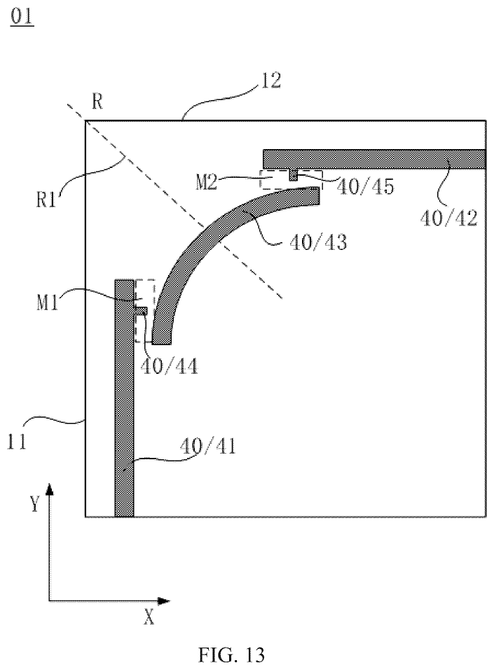

FIG. 13 is a partially enlarged schematic diagram of a display panel according to some embodiments of the present disclosure.

As shown in FIG. 13, in some embodiments of the present disclosure, the first retaining wall structure 40 further includes a second gap retaining wall 45 located between the second side retaining wall 42 and the arc-shaped retaining wall 43. That is, the second gap retaining wall 45 may be arranged in the second gap M2.

The second gap retaining wall 45 extends along the first direction Y, and one of the second side retaining wall 42 and the arc-shaped retaining wall 43 is connected to the second gap retaining wall 45.

In some embodiments of the present disclosure, the second gap retaining wall 45 is arranged between the arc-shaped retaining wall 43 and the second side retaining wall 42, so that the second gap retaining wall 45 may be used to block the first organic layer 302 that overflows to the second gap M2, which is beneficial to further preventing the first organic layer 302 from overflowing out from the second gap M2, thereby further improving the encapsulation reliability.

In some embodiments of the present disclosure, as shown in FIG. 12, the second gap retaining wall 45 is closer to the first edge 11 than the end of the arc-shaped retaining wall 43 adjacent to the second side retaining wall 42. In this way, on the one hand, it is beneficial to avoiding that the second gap retaining wall 45 completely blocks the second gap M2, thereby affecting the requirement for the first organic layer 302 to overflow to the second gap M2 during leveling, and on the other hand, it is beneficial to avoiding a steep corner when the first organic layer 302 transitions from the second side retaining wall 42 to the arc-shaped retaining wall 43.

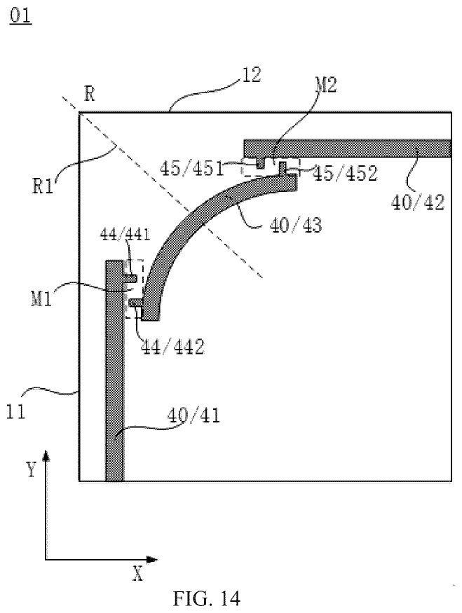

FIG. 14 is a partially enlarged schematic diagram of a display panel according to some embodiments of the present disclosure.

In some embodiments of the present disclosure, as shown in FIG. 14, a plurality of second gap retaining walls 45 are formed between the second side retaining wall 42 and the arc-shaped retaining wall 43, and the plurality of second gap retaining walls 45 are arranged along the second direction X. Along the second direction X, at least some of the second gap retaining walls 45 overlap.

For example, as shown in FIG. 14, the second gap retaining walls 45 include a third sub-gap retaining wall 451 and a fourth sub-gap retaining wall 452. The third sub-gap retaining wall 451 is located on a side of the fourth sub-gap retaining wall 452 adjacent to the first edge 11. The third sub-gap retaining wall 451 is connected to the second side retaining wall 42 and separated from the arc-shaped retaining wall 43. The fourth sub-gap retaining wall 452 is connected to the arc-shaped retaining wall 43 and separated from the second side retaining wall 42.

Along the second direction X, the third sub-gap retaining wall 451 overlaps with the fourth sub-gap retaining wall 452.

In some embodiments of the present disclosure, a plurality of second gap retaining walls 45 are formed between the second side retaining wall 42 and the arc-shaped retaining wall 43, and the plurality of second gap retaining walls 45 are arranged along the second direction X, which is beneficial to sequentially blocking the first organic layer 302 using the second gap retaining walls 45, thereby further improving the possibility of preventing the first organic layer 302 from overflowing out from the second gap M2, and improving the encapsulation reliability.

In addition, at least some of the second gap retaining walls 45 overlap along the second direction X, which is beneficial to enabling the second gap retaining walls 45 to comprehensively block the first organic layer 302 flowing into the second gap M2 along the first direction Y, thereby improving the possibility of preventing the first organic layer 302 from overflowing out from the second gap M2.

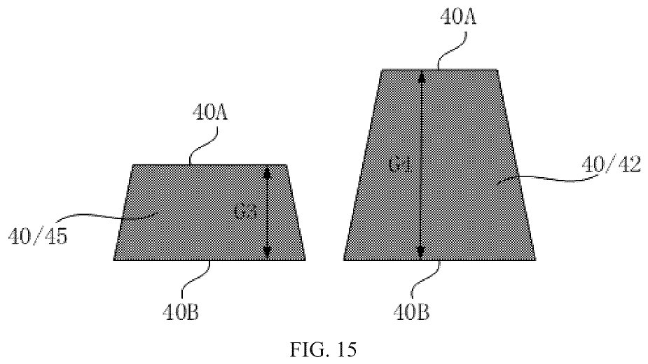

FIG. 15 is a comparative cross-sectional schematic diagram of a second gap retaining wall and a second side retaining wall according to some embodiments of the present disclosure.

In some embodiments of the present disclosure, as shown in FIG. 15, the height G3 of the second gap retaining wall 45 is less than the height G4 of the second side retaining wall 42. That is, G3<G4.

As can be seen from the above analysis, in the display panel 01, the cross-section of the first retaining wall structure 40 along the thickness direction is generally an isosceles trapezoid. The “upper” surface 40A of the first retaining wall structure 40 is located on a side of the “lower” surface 40B away from the substrate 10. The higher the first retaining wall structure 40 is, the smaller the area of the “upper” surface of the first retaining wall structure 40 is generally.

In some embodiments of the present disclosure, the height G3 of the second gap retaining wall 45 is smaller than the height G4 of the second side gap retaining wall 42, which can enable the area of the “upper” surface of the second gap retaining wall 45 to be relatively large, thereby helping to increase the connection area between the first inorganic layer 301 and the second inorganic layer 303 on the “upper” surface of the second gap retaining wall 45, improving the blocking capability of the first organic layer 302, and further improving the possibility of preventing the first organic layer 302 from overflowing out from the second gap M2.

As shown in FIG. 12 to FIG. 14, in some embodiments of the present disclosure, the structure at the position where the arc-shaped retaining wall 43 is adjacent to the first side retaining wall 41 may be the same as the structure at the position where the arc-shaped retaining wall 43 is adjacent to the second side retaining wall 42. In this way, the complexity of the first retaining wall structure 40 can be reduced, thereby facilitating reduction of the preparation cost.

In some embodiments of the present disclosure, as shown in FIG. 1, the display panel 01 may include a plurality of first included angles R (for example, four), and structural designs of the encapsulation layer 30 at each first included angle R are the same, so as to further reduce the structural complexity of the display panel 01 and to reduce the preparation cost.

Further, the display panel 01 may further include a second retaining wall structure 50 located on a side of the first retaining wall structure 40 adjacent to the edge of the display panel 01. The second retaining wall structure 50 may further block the overflow of the first organic layer 302, which is beneficial to further improving the encapsulation reliability.

The contour shape of the second retaining wall structure 50 may be any one of the contour shapes of the first retaining wall structure 40 in the above embodiments. At the same first included angle R of the display panel 01, the contour shape of the second retaining wall structure 50 may be the same as the contour shape of the first retaining wall structure 40. In this way, the complexity of the retaining wall structure in the display panel can be reduced, thereby helping to reduce the preparation difficulty of the display panel.

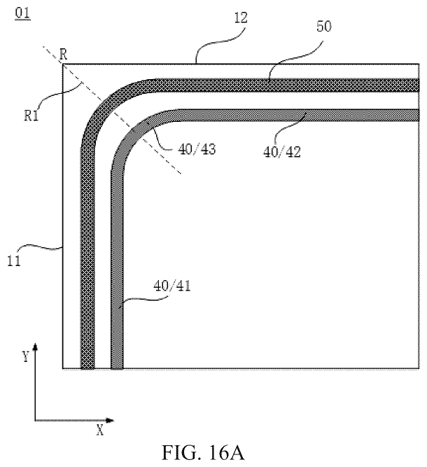

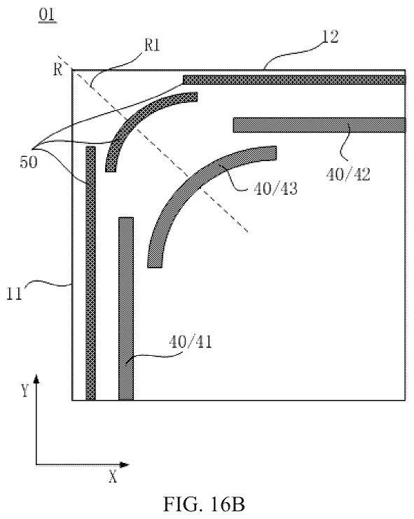

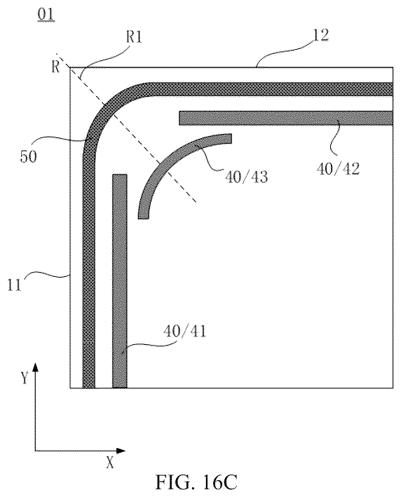

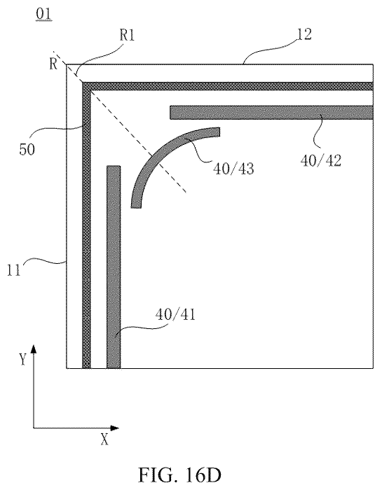

For example, as shown in FIG. 16A and FIG. 16B, FIG. 16A is a partial enlarged schematic diagram of a display panel according to some embodiments of the present disclosure, and FIG. 16B is a partial enlarged schematic diagram of a display panel according to some embodiments of the present disclosure. The contour shape of the second retaining wall structure 50 is the same as the contour shape of the first retaining wall structure 40.

At the same first included angle R of the display panel 01, the contour shape of the second retaining wall structure 50 may also be different from the contour shape of the first retaining wall structure 40. In this way, on the one hand, the structural diversity of the display panel 01 can be increased. On the other hand, the solid portion of the second retaining wall structure 50 can correspond to the weaker portion of the first retaining wall structure 40, and even if the first organic layer 302 overflows out from the first retaining wall structure 40, it can also be blocked by the second retaining wall structure 50, which is beneficial to further improving the encapsulation reliability.

For example, as shown in FIG. 16C and FIG. 16D, FIG. 16C is a partial enlarged schematic diagram of a display panel according to some embodiments of the present disclosure, and FIG. 16D is a partial enlarged schematic diagram of a display panel according to some embodiments of the present disclosure. The contour shape of the second retaining wall structure 50 is different from the contour shape of the first retaining wall structure 40.

It should be noted that, as shown in FIG. 16D, since the first organic layer 302 does not need to overflow in a large amount to the corner position of the second retaining wall structure 50 adjacent to the first included angle R, the second retaining wall structure 50 may include a right-angle structure at the first included angle R.

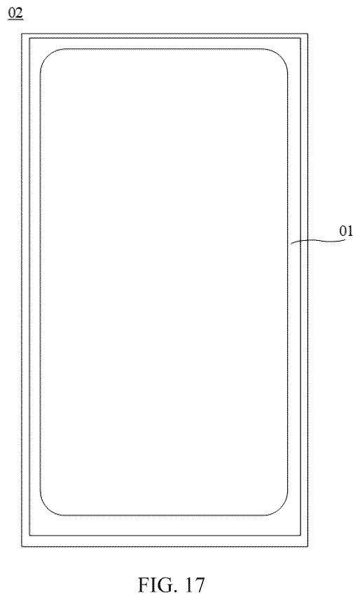

FIG. 17 is a schematic diagram of a display device according to some embodiments of the present disclosure.

Some embodiments of the present disclosure provide a display device 02. As shown in FIG. 17, the display device 02 includes the display panel 01 provided by the above embodiments. For example, the display device 02 is an electronic device such as a mobile phone, a computer, a television, and a vehicle-mounted display, which is not specifically limited in the present disclosure.

In the display device 02, the arc-shaped structure 33 is arranged between the first side structure 31 and the second side structure 32, and the angle bisector of the first included angle R passes through the arc-shaped structure 33, so that a portion of the encapsulation layer 30 adjacent to the vertex of the first included angle R includes the arc-shaped structure 33, which is beneficial to avoid a relatively steep corner when the first side structure 31 of the encapsulation layer 30 transitions to the second side structure 32 through the arc-shaped structure 33, thereby solving the problem of voids or bulging and overflow in the region of the encapsulation layer 30 adjacent to the first included angle R, and further improving the encapsulation reliability of the encapsulation layer 30.

The above are merely exemplary embodiments of the present disclosure, which, as mentioned above, are not used to limit the present disclosure. Whatever within the principles of the present disclosure, including any modification, equivalent substitution, improvement, etc., shall fall into the protection scope of the present disclosure.

What is claimed is:

1. A display panel, comprising:
a substrate comprising a first edge and a second edge intersecting with each other, wherein the first edge extends along a first direction, the second edge extends along a second direction, the first direction intersects with the second direction, an included angle between the first edge and the second edge is a first included angle, and the first included angle is a right angle;
a device layer located on a side of the substrate; and
an encapsulation layer located on a side of the device layer away from the substrate, wherein the encapsulation layer covers the device layer along a direction perpendicular to a plane of the substrate; and the encapsulation layer comprises a first side structure, a second side structure, and an arc-shaped structure located between the first side structure and the second side structure,
wherein the first side structure is adjacent to the first edge, the second side structure is adjacent to the second edge, and an angular bisector of the first included angle passes through the arc-shaped structure.

2. The display panel according to claim 1, wherein a minimum distance between the first side structure and the first edge is D1, a minimum distance between the second side structure and the second edge is D2, and a minimum distance between a vertex of the first included angle and the arc-shaped structure is D3,
wherein D3 is greater than a lesser one of D1 and D2.

3. The display panel according to claim 2, wherein D3 is not greater than three times of a greater one of D1 and D2.

4. The display panel according to claim 1, wherein a central angle corresponding to the arc-shaped structure is not greater than 180°.

5. The display panel according to claim 1, wherein one end of the arc-shaped structure is connected to the first side structure, and another end of the arc-shaped structure is connected to the second side structure.

6. The display panel according to claim 5, wherein a central angle corresponding to the arc-shaped structure is a second included angle, and an angular bisector of the second included angle coincides with the angular bisector of the first included angle; or
wherein a central angle corresponding to the arc-shaped structure is a second included angle, and an angular bisector of the second included angle does not coincide with the angular bisector of the first included angle.

7. The display panel according to claim 5, wherein an extension line of the first side structure intersects with an extension line of the second side structure, an included angle between the arc-shaped structure and the extension line of the first side structure is a third included angle, and an included angle between the arc-shaped structure and the extension line of the second side structure is a fourth included angle, and
wherein an angle degree of the third included angle is different from an angle degree of the fourth included angle.

8. The display panel according to claim 5, wherein one end of the arc-shaped structure is connected to an end of the first side structure facing the second edge, and another end of the arc-shaped structure is connected to an end of the second side structure facing the first edge.

9. The display panel according to claim 1, further comprising: a first retaining wall structure, wherein the encapsulation layer comprises a first inorganic layer, a second inorganic layer, and a first organic layer located between the first inorganic layer and the second inorganic layer, the first inorganic layer is connected to the second inorganic layer at the first retaining wall structure, and the first retaining wall structure is configured to block the first organic layer, and
wherein the first retaining wall structure comprises a first side retaining wall, a second side retaining wall and an arc-shaped retaining wall, the first side retaining wall extends along the first direction, the second side retaining wall extends along the second direction, the first side structure of the encapsulation layer is arranged on the first side retaining wall, the second side structure of the encapsulation layer is arranged on the second side retaining wall, and the arc-shaped structure of the encapsulation layer is arranged on the arc-shaped retaining wall.

10. The display panel according to claim 9, wherein one end of the arc-shaped retaining wall is connected to the first side retaining wall, and another end of the arc-shaped retaining wall is connected to the second side retaining wall; and the first side retaining wall intersects with the second side retaining wall, and a vertex where the first side retaining wall intersects with the second side retaining wall is located between a vertex of the first included angle and the arc-shaped retaining wall.

11. The display panel according to claim 9, wherein the first side retaining wall is separated from the arc-shaped retaining wall, and along the second direction, the first side retaining wall overlaps with the arc-shaped retaining wall, and
wherein a first gap is formed between the first side retaining wall and the arc-shaped retaining wall, and the first inorganic layer is connected to the second inorganic layer in the first gap.

12. The display panel according to claim 11, wherein a minimum distance between the first side retaining wall and the arc-shaped retaining wall is H1, and a length of the first side retaining wall overlapping with the arc-shaped retaining wall along the second direction is H2, where H2>H1; or
wherein the arc-shaped retaining wall is located on a side of the first side retaining wall away from the first edge.

13. The display panel according to claim 11, wherein the first retaining wall structure comprises a first gap retaining wall located between the first side retaining wall and the arc-shaped retaining wall, the first gap retaining wall extends along the second direction, and at least one of the first side retaining wall and the arc-shaped retaining wall is connected to the first gap retaining wall.

14. The display panel according to claim 13, wherein a plurality of first gap retaining walls are provided between the first side retaining wall and the arc-shaped retaining wall, the plurality of first gap retaining walls are arranged along the first direction, and at least some of the plurality of first gap retaining walls overlap along the first direction.

15. The display panel according to claim 13, wherein a height of the first gap retaining wall is less than a height of the first side retaining wall.

16. The display panel according to claim 11, wherein the second side retaining wall is separated from the arc-shaped retaining wall, and the second side retaining wall overlaps with the arc-shaped retaining wall along the first direction, and
wherein a second gap is formed between the second side retaining wall and the arc-shaped retaining wall, and the first inorganic layer is connected to the second inorganic layer in the second gap.

17. The display panel according to claim 16, wherein a minimum distance between the second side retaining wall and the arc-shaped retaining wall is L1, and a length of the second side retaining wall overlapping with the arc-shaped retaining wall along the first direction is L2, where L2>L1; or
wherein the arc-shaped retaining wall is located on a side of the second side retaining wall away from the second edge.

18. The display panel according to claim 16, wherein the first retaining wall structure further comprises a second gap retaining wall located between the second side retaining wall and the arc-shaped retaining wall, the second gap retaining wall extends along the first direction, and at least one of the second side retaining wall and the arc-shaped retaining wall is connected to the second gap retaining wall.

19. The display panel according to claim 18, wherein a plurality of second gap retaining walls are provided between the second side retaining wall and the arc-shaped retaining wall, the plurality of second gap retaining walls are arranged along the second direction, and at least some of the plurality of second gap retaining walls overlap along the second direction; or
wherein a height of the second gap retaining wall is less than a height of the second side retaining wall.

20. A display device, comprising a display panel, wherein the display panel comprises:
a substrate comprising a first edge and a second edge intersecting with each other, wherein the first edge extends along a first direction, the second edge extends along a second direction, the first direction intersects with the second direction, an included angle between the first edge and the second edge is a first included angle, and the first included angle is a right angle;
a device layer located on a side of the substrate; and
an encapsulation layer located on a side of the device layer away from the substrate, wherein the encapsulation layer covers the device layer along a direction perpendicular to a plane of the substrate; and the encapsulation layer comprises a first side structure, a second side structure, and an arc-shaped structure located between the first side structure and the second side structure,
wherein the first side structure is adjacent to the first edge, the second side structure is adjacent to the second edge, and an angular bisector of the first included angle passes through the arc-shaped structure.
